(19) United States
(12) Patent Application Publication
(10) Pub. No.: US 2018/0277667 A1
(43) Pub. Date: Sep. 27, 2018

(54) SEMICONDUCTOR DEVICE

(71) Applicant: KABUSHIKI KAISHA TOSHIBA, Tokyo (JP)

(72) Inventors: Hideki SEKIGUCHI, Yokkaichi Mie (JP); Keiko KAWAMURA, Yokkaichi Mie (JP); Kaori FUSE, Mie Mie (JP); Akira KOMATSU, Yokkaichi Mie (JP); Ryohei KITAO, Yokkaichi Mie (JP); Satoshi WAKATSUKI, Yokkaichi Mie (JP); Atsuko SAKATA, Yokkaichi Mie (JP); Koichi KUBO, Mie Mie (JP)

(21) Appl. No.: 15/690,251

(22) Filed: Aug. 29, 2017

(30) Foreign Application Priority Data
Mar. 23, 2017 (JP) 2017-057715

(51) Int. Cl. H01L 29/739; H01L 29/45; H01L 29/49

(52) U.S. Cl. CPC H01L 29/7397; H01L 29/4975; H01L 29/456

(57) ABSTRACT

A semiconductor device includes first and second electrodes, first semiconductor region of first conductivity type between the first and second electrodes, a second semiconductor region of second conductivity type between the first semiconductor region and the first electrode, a third semiconductor region of the second conductivity type between the first semiconductor region and the second electrode, a fourth semiconductor region of the first conductivity type between the third semiconductor region and the second electrode, a plurality of third electrodes between the second electrode and the first semiconductor region, wherein a gate insulating film is between each third electrode and the third semiconductor region, a fourth electrode extending between the third semiconductor region and the second electrode and electrically connected to the third semiconductor region and the second electrode, and a first insulating film between the second and electrodes. The fourth electrode is in ohmic contact with the third semiconductor region.

This application is based upon and claims the benefit of priority from Japanese Patent Application No. 2017-057715, filed Mar. 23, 2017, the entire contents of which are incorporated herein by reference.

### FIELD

Embodiments described herein relate generally to a semiconductor device.

### BACKGROUND

As examples of power semiconductor devices for electric power control, an IGBT (Insulated Gate Bipolar Transistor), a MOSFET (metal-oxide-semiconductor field-effect transistor), and the like are used. These devices are now required to have reduced power loss and low capacitance characteristics during switching operation. To meet these demands, there is an IGBT having, for example, a trench gate structure and a MOSFET having the trench gate structure.

### DESCRIPTION OF THE DRAWINGS

FIG. 1 is a schematic cross-sectional view of a semiconductor device according to a first embodiment.

FIG. 2 is an enlarged view of a trench contact section shown in FIG. 1.

FIG. 3 is a schematic cross-sectional view illustrating an ON state of the semiconductor device according to the first embodiment.

FIG. 4 is a schematic cross-sectional view of a semiconductor device according to a first comparative example.

FIG. 5 is an enlarged view of a trench contact section shown in FIG. 4.

### DETAILED DESCRIPTION

Embodiments provide a semiconductor device capable mitigating an influence on threshold voltage characteristics.

In general, according to one embodiment, a semiconductor device includes first and second electrodes, a first semiconductor region of a first conductivity type between the first and second electrodes, a second semiconductor region of a second conductivity type between the first semiconductor region and the first electrode, a third semiconductor region of the second conductivity type between the first semiconductor region and the second electrode, a fourth semiconductor region of the first conductivity type between the third semiconductor region and the second electrode, a plurality of gate insulating films between the first semiconductor region and the second electrode, a plurality of third electrodes between the second electrode and the first semiconductor region, wherein each of the gate insulating films is between one of the third electrodes and at least the third semiconductor region, a fourth electrode extending between the third semiconductor region and the second electrode and electrically connected to the third semiconductor region and the second electrode, and a first insulating film between the second electrode and the third electrodes. The fourth electrode is in ohmic contact with the third semiconductor region.

Embodiments will be described hereinafter with reference to the drawings. In the description below, the same constituent elements are denoted by the same reference signs and the description of the constituent elements already discussed is omitted as appropriate.

It is noted that the relationship between a thickness and a width of each section, a proportion of magnitudes of sections, and the like in the drawings are not necessarily identical those in an actual device. Furthermore, even the same sections are often illustrated with different sizes or different proportions depending on the drawing.

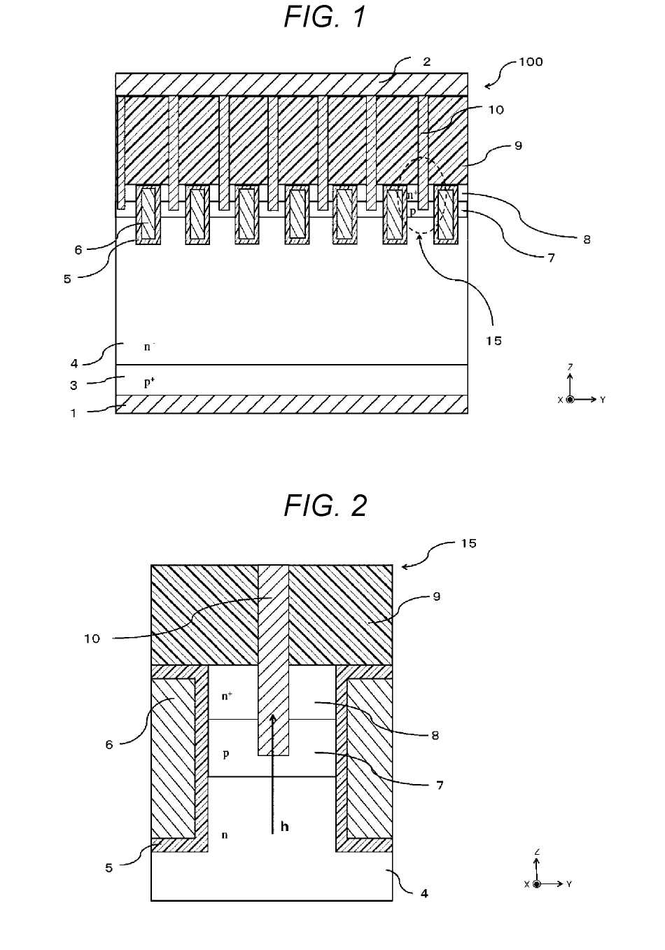

(First Embodiment) A first embodiment of the present disclosure will be described with reference to FIG. 1. FIG. 1 is a schematic cross-sectional view of a semiconductor device 100 according to the first embodiment. In the drawings shown below, a three-dimensional coordinate system (XYZ coordinate system) is used to represent directions of the semiconductor device 100. An X direction and a Y direction are orthogonal to each other in the same plane. A Z direction is orthogonal to the X direction and the Y direction.

In the description below, expressions of n⁺, n, n⁻, p⁺, and p represent relative levels of impurity concentrations of the respective conductivity types. That is, the impurity concentrations are relatively high to relatively low in the order of a region with “+”, a region without any sign, and a region with “−”. Furthermore, an expression “impurity concentration is high” may be paraphrased by “carrier concentration is high”.

The embodiments described below may be implemented by interchanging the conductivity types p and n of semiconductor regions.

A configuration of the semiconductor device 100 according to the first embodiment will first be described. A case where the semiconductor device 100 is an IGBT will be described by way of example. As shown in FIG. 1, the semiconductor device 100 includes a collector electrode 1, an emitter electrode 2, a p⁺ collector region 3, an n⁻ drift region 4, gate insulating films 5, gate electrodes 6, a p base region 7, an n⁺ emitter region 8, an oxide film 9, and a contact electrode 10.

The semiconductor device 100 according to the first embodiment has an upper-lower electrode structure in which various semiconductor regions are provided between the collector electrode 1 and the emitter electrode 2. The direction from the collector electrode 1 to the emitter electrode 2 is the Z direction.

In the semiconductor device 100, the p⁺ collector region 3 and the n⁻ drift region 4 are provided between the collector electrode 1 and the emitter electrode 2. The p⁺ collector region 3 is electrically connected to the collector electrode 1. The n⁻ drift region 4 is located between the emitter electrode 2 and the p⁺ collector region 3.

In the Z direction, the p base region 7 and the n⁺ emitter region 8 are located between the n⁻ drift region 4 and the emitter electrode 2. The p base region 7 is located on the n⁻ drift region 4 in the Z direction. The n+ emitter region 8 is located on the p base region 7 in the Z direction.

Each of the gate electrodes 6 are separated from the n⁻ drift region 4, the p base region 7, and the n⁺ emitter region 8 by each gate insulating film 5 disposed therearound. The gate electrodes 6 extend in the X direction and the Z direction. A plurality of the gate electrodes 6 are provided spaced from one another in the Y direction.

The oxide film 9 is provided between the n⁺ emitter region 8 and the emitter electrode 2. The oxide film 9 may be provided between the gate electrodes 6 and the emitter electrode 2 and is not necessarily provided on the n⁺ emitter region 8. Furthermore, the contact electrode 10 is provided between the p base region 7 and the emitter electrode 2. The contact electrode 10 extends through the oxide film 9 in the Z direction and is electrically connected to the emitter electrode 2. A contact portion of the contact electrode 10, which contacts the p base region 7, is silicided, to form a silicide contact region between at least a portion of the interface between the contact electrode 10 and the p base region 7. The p base region 7 and the n⁺ emitter region 8 are electrically connected to the contact electrode 10.

The semiconductor regions, i.e., the n⁻ drift region 4, the p base region 7, and the n⁺ emitter region 8 located between the adjacent gate electrodes in the Y direction are generically referred to as a “trench contact section 15”.

An example of a material of each constituent element will now be described.

A main component of each of the plurality of semiconductor regions provided between the collector electrode 1 and the emitter electrode 2 is, for example, silicon (Si). Alternatively, the main component of each of the plurality of semiconductor regions may be silicon carbide (SiC), gallium nitride (GaN) or the like. As an impurity element of the conductivity type such as n⁺, n, and n⁻, phosphorus (P) or arsenic (A), for example, is applied. As an impurity element of the conductivity type such as p⁺ and p, boron (B), for example, is applied. Moreover, the semiconductor device 100 exhibits similar effects even if the conductivity types of p and n are interchanged.

A material of the collector electrode 1 and a material of the emitter electrode 2 are, for example, a metal including at least one selected from a group consisting of aluminum (Al), titanium (Ti), nickel (Ni), tungsten (W), gold (Au), copper (Cu), and the like. A material of the gate electrodes 6 includes, for example, polysilicon. In addition, a material of the gate insulating films 5 includes, for example, silicon oxide or silicon nitride.

A material of the contact electrode 10 is a material having a high work function such as cobalt (Co), ruthenium (Ru), or nickel (Ni) exhibiting ohmic characteristics for the p base region 7.

<Functions and Effects> Functions and effects of the first embodiment will be described with reference to FIGS. 1 to 7.

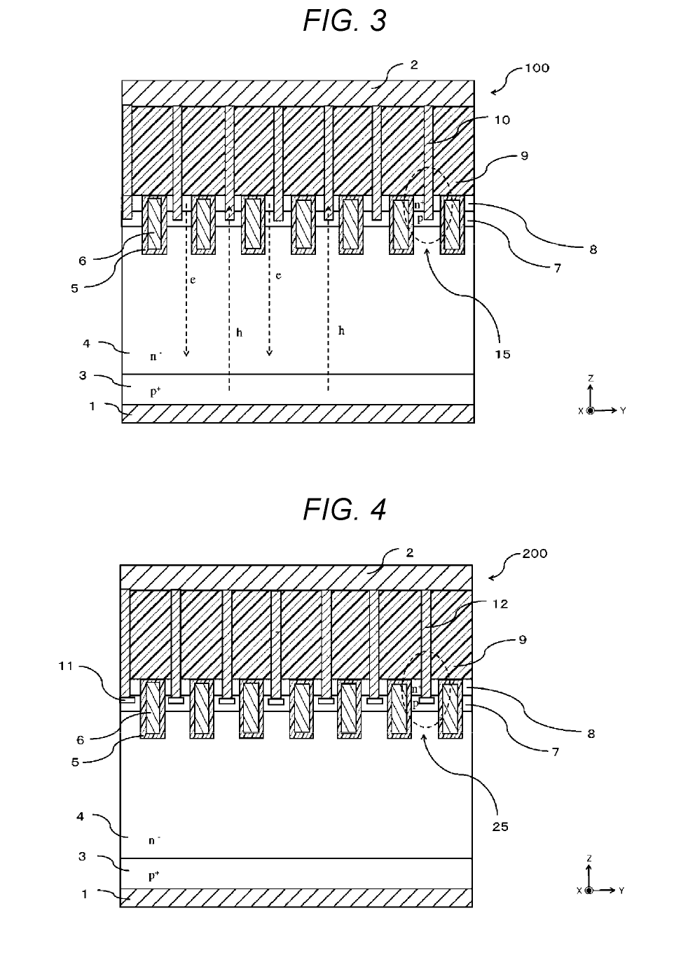

FIG. 2 is an enlarged view of the trench contact section 15 shown in FIG. 1. The n⁻ drift region 4, the p base region 7, and the n⁺ emitter region 8 are stacked one over the other in the Z direction. While the operation of the IGBT will be described later with reference to FIG. 3, FIG. 2 also illustrates a state in which a hole current (h) flows into the contact electrode 10.

The functions of the IGBT as the semiconductor device 100 will be described with reference to FIG. 3.

In the semiconductor device 100, a higher potential is applied to the collector electrode 1 than the potential applied to the emitter electrode 2, and a potential equal to or higher than a threshold potential (Vth) is supplied to the gate electrodes 6. In this case, an n channel region is formed on a surface of the p base region 7 along each gate insulating film 5, thereby turning on an IGBT section. Namely, an electron current (e) flows from the n⁺ emitter region 8 to the p base region 7, the n⁻ drift region 4, and the p⁺ collector region 3 in this order. Accordingly, the hole current (h) flows from the p⁺ collector region 3 to the n⁻ drift region 4, the p base region 7, and the contact electrode 10 in this order.

As described so far, the IGBT is turned on by applying a voltage equal to or higher than a threshold voltage to each gate electrode 6; therefore, a fluctuation of the threshold voltage adversely influences the performance of the semiconductor device 100. While forming many device sections by narrowing the pitch of (i.e., spacing between) the trench contact sections 15 contributes to improving efficiency, this, in turn, possibly causes the fluctuation of the threshold voltage. To address this issue, the semiconductor device 100 according to the first embodiment provides a structure in that the contact electrode 10 made from a metal having the ohmic characteristics, i.e., can make ohmic contact with the n⁻ drift region 4, and the p⁺ collector region 3, which prevents even the narrowed pitches of the trench contact sections 15 from adversely influencing the threshold voltage. Thus the p base region 7 has a uniform impurity concentration.

Functions of a semiconductor device 200 according to a first comparative example will next be described.

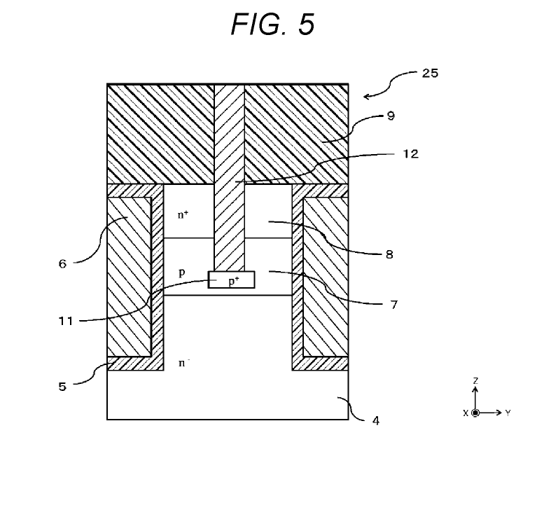

FIG. 4 is a schematic cross-sectional view of the semiconductor device 200 according to the first comparative example. FIG. 5 is an enlarged view of a trench contact section 25 shown in FIG. 4. The semiconductor device 200 according to the first comparative example includes the collector electrode 1, the emitter electrode 2, the p⁺ collector region 3, the n⁻ drift region 4, the gate insulating films 5, the gate electrode 6, the p base region 7, the n⁺ emitter region 8, the oxide film 9, a p⁺ contact region 11, and a metal electrode 12. The metal electrode 12 is formed of, for example, tungsten (W).

The semiconductor device 200 according to the first comparative example differs from the semiconductor device 100 according to the first embodiment in that semiconductor device 200 includes not the contact electrode 10 but the metal electrode 12, and the p⁺ contact region 11 is provided within the p base region 7 in contact with the base of the metal electrode 12. The semiconductor device 200 is the same as the semiconductor device 100 in the other respects.

The p⁺ contact region 11 is higher in impurity concentration than the p base region 7 and connected to an end of the metal electrode 12. This is intended to reduce the contact resistance generated when the p⁺ contact region 11 is electrically connected to the metal electrode 12.

However, since the trench contact section 25 is present around the p⁺ contact region 11, a dopant of the p⁺ layer is diffused to influence the channel region. Owing to this, when the pitch of the trench contact sections 25 are reduced, the reduced pitch often influences the threshold voltage.

In the semiconductor device 100 according to the first embodiment, by contrast, the p⁺ contact region 11 is not provided. The metal electrode 12 is replaced by the contact electrode 10 as an alternative. The contact electrode 10 reduces the contact resistance with the p base region 7, so that there is no need to provide the p⁺ contact region 11. When the pitch is narrowed in this construct, the dopant of the p⁺ layer is not diffused because there is no p⁺ contact region 11; therefore, it is possible to suppress the influence of the narrowed pitch on the threshold voltage.

In the semiconductor device 100 according to the first embodiment, the metal electrode 12 is replaced by the ohmic contact electrode without providing the p⁺ contact region in the bottom portion of the trench contact section 15. Owing to this, even when the pitch of the trench contact sections 15 is narrowed, it is possible to mitigate the influence of the narrowed pitch on the threshold voltage of the gate voltage. Furthermore, many device sections can be formed by reducing a distance between the trench contact sections 15, so that it is possible to improve efficiency. Moreover, chip shrinkage can contribute to improving characteristics such as speed enhancement and power saving.

While the IGBT structure has been described by way of example, the IGBT structure may be replaced by a MOSFET structure. In this case, similarly to the aforementioned embodiment, it is possible to attain the same effects as a result of reducing the device size.

While the embodiment and the modified embodiment have been described, the embodiment and the modified embodiment have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. A specific configuration of each constituent element included in the embodiments can be selected by a person skilled in the art, as appropriate, from well-known techniques. The accompanying claims and their equivalents are intended to cover such forms or modifications as would fall within the scope and spirit of the inventions.

1. A semiconductor device, comprising:
a first electrode;
a second electrode;
a first semiconductor region of a first conductivity type between the first electrode and the second electrode;
a second semiconductor region of a second conductivity type between the first semiconductor region and the first electrode;
a third semiconductor region of the second conductivity type between the first semiconductor region and the second electrode;
a fourth semiconductor region of the first conductivity type between the third semiconductor region and the second electrode;
a plurality of gate insulating films between the first semiconductor region and the second electrode;
a plurality of third electrodes between the second electrode and the first semiconductor region, wherein each of the gate insulating films is between one of the third electrodes and at least the third semiconductor region;
a fourth electrode extending between the third semiconductor region and the second electrode and electrically connected to the third semiconductor region and the second electrode; and
a first insulating film between the second electrode and the third electrodes, wherein
a portion of the fourth electrode, which contacts the third semiconductor region, is in ohmic contact with the third semiconductor region.

2. The semiconductor device according to claim 1, wherein
at least a portion of the fourth electrode in contact with the third semiconductor region is silicided.

3. The semiconductor device according to claim 1, wherein the fourth electrode is a contact electrode containing at least one of cobalt, ruthenium, and nickel.

4. The semiconductor device according to claim 1, wherein the fourth electrode extends inwardly of the third semiconductor region and terminates therein.

5. The semiconductor device according to claim 1, wherein the portion of the fourth electrode extending inwardly of the third semiconductor region is spaced from a gate insulating film on either side thereof by a portion of the third semiconductor region.

6. The semiconductor device according to claim 1, wherein
a portion of the third semiconductor region is interposed between the portion of the fourth electrode extending inwardly of the third semiconductor region and the second semiconductor region, and
the impurity concentration of the second conductivity type impurity in the third semiconductor region between the fourth electrode and the second semiconductor region is uniform.

7. The semiconductor device according to claim 6, wherein the impurity concentration of the second conductivity type impurity in the second semiconductor region is greater than the impurity concentration of the second conductivity type impurity in the third semiconductor region.

8. The semiconductor device according to claim 6, wherein the fourth electrode extends through the fourth semiconductor region.

9. A semiconductor device; comprising:
a first electrode;
a second electrode;
a first semiconductor region of a first conductivity type between the first electrode and the second electrode;
a second semiconductor region of a second conductivity type between the first semiconductor region and the first electrode;
a third semiconductor region of the second conductivity type between the first semiconductor region and the second electrode;
a fourth semiconductor region of the first conductivity type between the third semiconductor region and the second electrode;
a plurality of gate insulating films between the first semiconductor region and the second electrode;
a plurality of third electrodes between the second electrode and the first semiconductor region, wherein each of the gate insulating films is between one of the third electrodes and at least the third semiconductor region;
a fourth electrode extending between the third semiconductor region and the second electrode and electrically connected to the third semiconductor region and the second electrode; and
a first insulating film between the second electrode and the third electrodes, wherein
the impurity concentration of the second conductivity type impurity in the third semiconductor region between the fourth electrode and the second semiconductor region is uniform.

10. The semiconductor device according to claim 9, wherein the impurity concentration of the second conductivity type impurity in the second semiconductor region is greater than the impurity concentration of the second conductivity type impurity in the third semiconductor region.

11. The semiconductor device according to claim 9, wherein the fourth electrode extends through the fourth semiconductor region.

12. The semiconductor device according to claim 9, further comprising a silicide region interposed between the fourth electrode and the third semiconductor region.

13. The semiconductor device according to claim 12, wherein the silicide region is composed of an element of the third semiconductor region and an element of the fourth electrode.

14. The semiconductor device according to claim 13, wherein the silicide region comprises one of cobalt silicide, ruthenium silicide, and nickel silicide.

15. The semiconductor device according to claim 12, wherein the fourth electrode extends inwardly of the third semiconductor region and terminates therein.

16. The semiconductor device according to claim 12, wherein a portion of the fourth electrode extending inwardly of the third semiconductor region is spaced from a gate insulating film on either side thereof by a portion of the third semiconductor region.

17. A semiconductor device, comprising:
a first electrode and a second electrode;
a first semiconductor region of a first conductivity type interposed between the first electrode and the second electrode;
a second semiconductor region including impurities of a second conductivity type interposed between the first semiconductor region and the second electrode;
a plurality of third electrodes, an insulating layer interposed between each third electrode and at least the second semiconductor region, each third electrode extending through the second semiconductor region and extending inwardly of the first semiconductor region, and located between the first semiconductor region and the second electrode; and
at least one fourth electrode extending between, and in electrical contact with, the second electrode and the second semiconductor region, wherein
the impurity concentration of the second conductivity type impurity in the second semiconductor region at least in a portion thereof between the fourth electrode and the first semiconductor region is uniform.

18. The semiconductor device according to claim 17, further comprising a silicide region located between, and electrically contacting, the second semiconductor region and the fourth electrode.

19. The semiconductor device according to claim 17, wherein the fourth electrode is in ohmic contact with the second semiconductor region.

20. The semiconductor device according to claim 17, further comprising:
a third semiconductor region of the second conductivity type interposed between the first semiconductor region and the second electrode.
